(19) United States
(12) Patent Application Publication
(10) Pub. No.: US 2008/0159565 A1
(43) Pub. Date: Jul. 3, 2008

(54) System and method for outputting audio data

(76) Inventor: Hee Young Kim, Seoul (KR)

Correspondence Address: CHA & REITER, LLC, 210 ROUTE 4 EAST STE 103, PARAMUS, NJ, 07652, US

(21) Appl. No.: 11/825,058

(22) Filed: Jul. 3, 2007

(30) Foreign Application Priority Data
Dec. 29, 2006 (KR) 2006-0138035

(51) Int. Cl. H03G 3/00

(52) U.S. Cl. 381/107

(57) ABSTRACT

A system and method for outputting audio data through a short-range wireless communication are disclosed. The system includes a headset for outputting audio data, adjusting a gain of a microphone in response to a change control signal of an output path of the audio data, and changing the output path of the audio data and an amplifying speaker for outputting the audio data provided through the headset.

### CLAIM OF PRIORITY

This application claims the benefit of the earlier filing date, pursuant to 35 USC 119, to that patent application entitled “SYSTEM AND METHOD FOR OUTPUTTING AUDIO DATA” filed in the Korean Intellectual Property Office on Dec. 29, 2006 and assigned Serial No. 2006-0138035, the contents of which are incorporated herein by reference.

### BACKGROUND OF THE INVENTION

1. Field of the Invention

The present invention relates to an audio system, and more particularly, to a system and method for outputting audio data through an amplifying speaker connected to a headset capable of outputting the audio data received from a portable terminal that can perform short-range wireless communication.

2. Description of the Related Art

In general, a Bluetooth network refers to a piconet having one master terminal and a plurality of slave terminals, which are interconnected according to the Bluetooth protocol. In one piconet, the plurality of slave terminals receive data from one master terminal. Additionally, a plurality of piconets may form a Bluetooth network. This is referred to as a scatternet. According to the present technology (Bluetooth ver. 2.0), the number of slave terminals is limited to a maximum of 7 in one piconet. However, as Bluetooth technology develops, the number of slave terminals used in one piconet may increase.

Recently, with the spread of portable terminals, a user can receive another user's data through a portable terminal and transmit this data to another user's portable terminal via Bluetooth communication. Also, users can perform telephone communication and listen to music in MP3 format, using a wireless headset that utilizes Bluetooth technology.

However, listening to such audio data is possible only when using a Bluetooth headset. Therefore, if one user wants to listen to audio data simultaneously with other users, a Bluetooth amplifying speaker must be additionally used. That is, the conventional audio system is disadvantageous in that it requires each user to purchase a headset and an amplifying speaker.

### SUMMARY OF THE INVENTION

In order to solve the above problems, the present invention allows multiple users to simultaneously listen to audio data in a portable terminal via short-range wireless communication.

The present invention allows an automatic change of output path of audio data according to connection/disconnection events between a headset and an amplifying speaker.

The present invention determines connection/disconnection through a built-in magnet of an amplifying speaker and a built-in Hall sensor of a headset, and automatically changes the output path of audio data outputted from the headset.

The present invention automatically adjusts microphone gain according to connection/disconnection events between a headset and an amplifying speaker.

In accordance with an aspect of the present invention, there is provided a system for outputting audio data that includes a headset for outputting audio data transmitted from inside/outside, adjusting gain of a microphone in response to a change control signal of an output path of the audio data, and changing the output path of the audio data and an amplifying speaker for outputting the audio data transmitted through the headset.

In accordance with another aspect of the present invention, there is provided a method for outputting audio data using a headset and an amplifying speaker. The method includes adjusting gain of a microphone of the headset when the headset reads connection to the amplifying speaker, changing an output path of the audio data to the amplifying speaker connected to the headset and transmitting the audio data to the changed output path.

In accordance with yet another aspect of the present invention there is provided a method for outputting audio data using a headset and an amplifying speaker. The method includes adjusting gain of a microphone of the headset when connection/disconnection of the amplifying speaker is detected, and changing an output path of the audio data, transmitting the audio data to the changed output path and outputting the transmitted audio data through the amplifying speaker.

### BRIEF DESCRIPTION OF THE DRAWINGS

The above and other features and advantages of the present invention will be more apparent from the following detailed description in conjunction with the accompanying drawings, in which:

FIG. 1 is a view illustrating a system for outputting audio data through short-range wireless communication according to the present invention;

FIG. 2 is a view illustration a system connected to a headset and an amplifying speaker, for outputting audio data according to an embodiment of the present invention;

FIG. 3 is a schematic block diagram illustrating a headset outputting audio data according to an embodiment of the present invention;

FIG. 4 is a view illustrating a procedure to output audio data transmitted through short-range wireless communication according to an embodiment of the present invention; and

FIG. 5 is a flow chart describing a method for outputting audio data transmitted through short-range wireless communication according to an embodiment of the present invention.

### DETAILED DESCRIPTION OF THE INVENTION

Hereinafter, embodiments of the present invention are described in detail with reference to the accompanying drawings.

The embodiments of the present invention will be described based on a Bluetooth headset. But it will be appreciated that the present invention is not limited by the embodiments, and instead the headset may be replaced with other devices, such as a wrist strap earphone, a stereo-headset, or a headphone, etc.

Also, audio data according to the present invention includes MP3 music data and voice data from a phone communication, etc., audible through the headset.

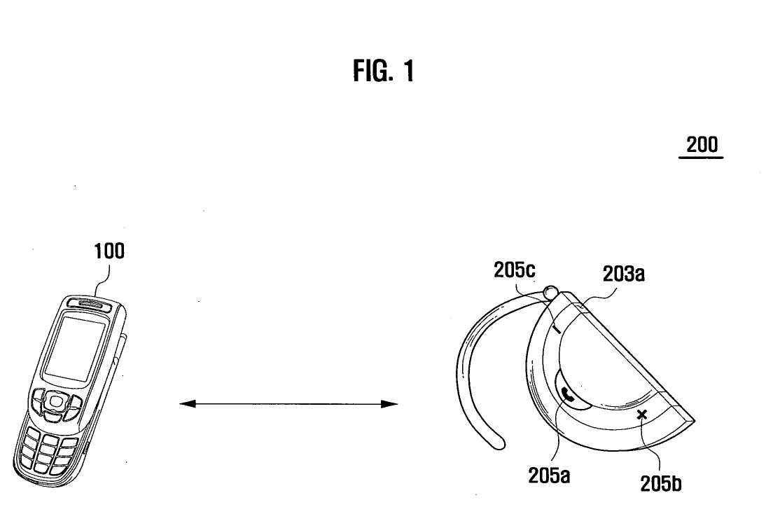

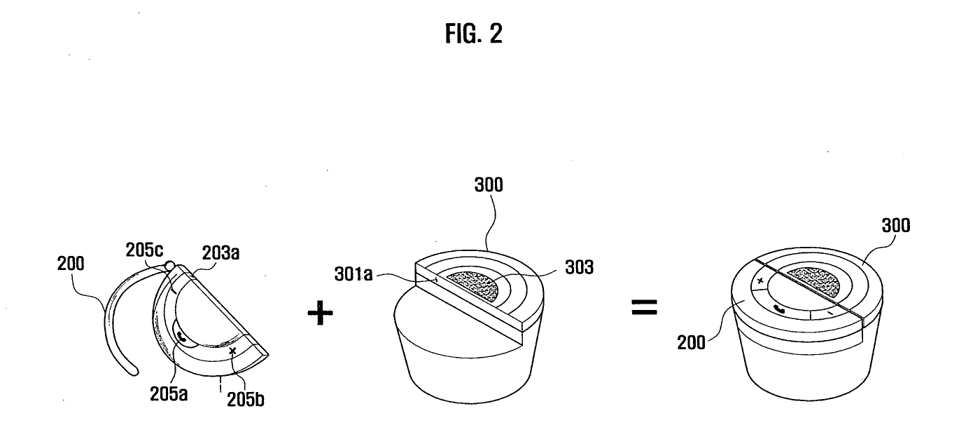

FIG. 1 is a view illustrating a system for outputting audio data through short-range wireless communication according to the present invention. FIG. 2 is a view illustration a system connected to a headset and an amplifying speaker, for outputting audio data according to an embodiment of the present invention.

Referring to FIGS. 1 and 2, the system includes a portable terminal 100 that can perform short-range wireless communication (hereinafter, referred to as Bluetooth communication); a headset 200 having a Hall senor, for performing Bluetooth communication and an amplifying speaker 300 having a magnet.

In particular, FIG. 2 shows a configuration where the headset 200 of FIG. 1 is mounted on the amplifying speaker 300 to output audio data to the amplifying speaker 300.

The portable terminal 100 is connected to the headset 200 according to the Bluetooth protocol and transmits audio data to the headset 200. The portable terminal 100 serves as a master terminal in a piconet, i.e., a Bluetooth network.

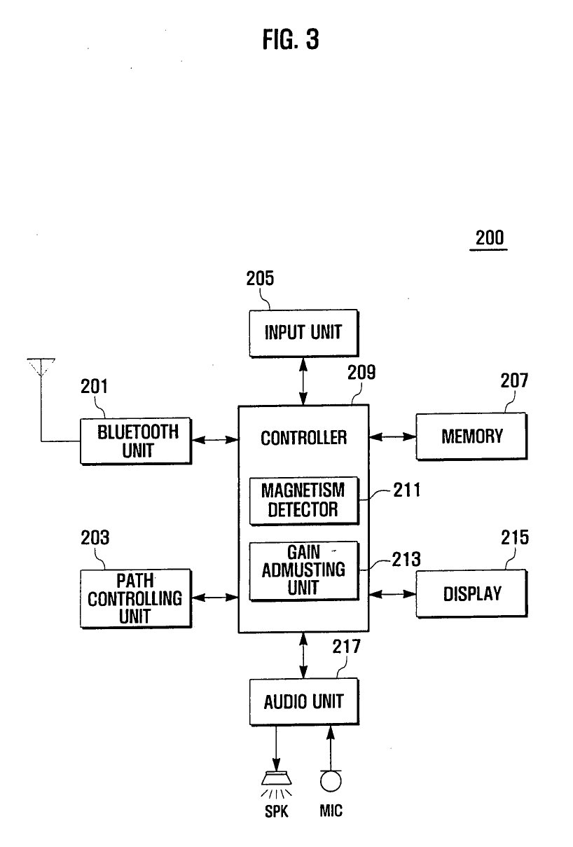

The headset 200 receives the audio data from the portable terminal 100 to output it. The headset 200 includes a path controller 203 (see FIG. 3) for changing a transmission path of the audio data to the amplifying speaker 300 and an input unit 205 (see FIG. 3) having volume adjustment buttons 205b and 205c, and a button 205a for executing communication of the headset 200 and power ON/OFF. The headset 200 serves as a slave terminal in the network.

Returning to FIGS. 1 and 2, the headset 200 includes a Hall sensor for detecting the magnet built into the amplifying speaker 300. Also, the headset 200 includes an output lead 203a (FIG. 1) to provide a transmission path of the audio data to the amplifying speaker 300. The configuration of the headset 200 will be described with reference to FIG. 3.

The amplifying speaker 300 outputs the audio data provided from the headset 200. To this end, the amplifying speaker 300 includes an input lead 301a, an external speaker 303, and a magnet (not shown). Also, the amplifying speaker 300 serves as a re-charger for the headset 200.

The input lead 301a is connected to the output lead 203a to receive the audio data from the headset 200.

The external speaker 303 outputs audio corresponding to the audio data that the input lead 301a received through the output lead 203a of the headset 200.

The headset 200 operates the Hall sensor (i.e., Hall IC) included in the headset 200. Here, the Hall sensor is a sensor that responds to a magnetic field.

FIG. 3 is a schematic block diagram illustrating a headset outputting audio data according to an embodiment of the present invention.

Referring to FIG. 3, the headset 200 includes a Bluetooth unit 201, a path controlling unit 203, an input unit 205, a memory 207, a controller 209, a 20 magnetism detector 211, a gain adjusting unit 213, a display 215, and an audio unit 217.

The Bluetooth unit 201 performs Bluetooth communication with other Bluetooth devices, through a Bluetooth antenna, based on the Bluetooth protocol. In particular, the Bluetooth unit 201 stores a host stack for administrating Bluetooth communication, and Bluetooth profile and application programs, etc., which can be selected according to the functions and conditions of external Bluetooth devices as communication targets. Also, the Bluetooth profile includes a hands-free (HF) profile for supporting a hands-free set, a headset (HS) profile for supporting a headset, and a cordless telephone profile (CTP) for supporting a cordless telephone, which may be selectively used according to external Bluetooth devices.

The path controlling unit 203 switches the switch, connected to the built-in speak SPK of the headset 200, to the output lead 203a, according to control of the controller 209, when the magnetism detector 211 of the controller 209 detects the magnetism of the magnet of the amplifying speaker 300, thereby providing a path for transmitting the audio data.

The input unit 205 includes a button unit for operating the headset 200. Here, the button unit includes a main button 205a (FIG. 1) for performing communication and power ON/OFF operations, and volume buttons 205b and 205c (FIG. 1) which adjust the volume of the headset 200. The input unit 205 provides control signals of the button unit to the controller 209.

The memory 207 stores a Bluetooth address BT_ADDR and a pin code PIN_CODE of the headset 200. The BT_ADDR and PIN_CODE are transmitted to the portable terminal 100 through the Bluetooth unit 201 as the headset 200 performs Bluetooth communication with the portable terminal 100.

The controller 209 detects magnetism generated by the magnet and then adjusts the gain of the microphone MIC. To this end, the controller 209 includes the magnetism detector 211 and the gain adjusting unit 213. The controller 209 controls the gain adjusting unit 213 to control the gain of the audio data inputted through the microphone MIC when the magnetism detector 211 detects the presents of a magnetic field. Also, the controller 209 changes the output path of the audio data transmitted from the portable terminal 100 to the amplifying speaker 300 when the magnetism detector 211 detects the magnetism.

The magnetism detector 211 detects the magnetic field generated by the magnet of the amplifying speaker 300. Also, the magnetism detector 211 may include a general Hall sensor (Hall IC). Here, the Hall sensor allows the switch, connected to the built-in speaker of the headset 200 by the detected magnetism, to contact the output lead 203a of the headset 200, thereby connecting the output lead 203a to the input lead of the amplifying speaker 300.

The gain adjusting unit 213 automatically adjusts the gain of audio data when the magnetism detector 211 detects magnetism, in which the audio data is inputted from the microphone MIC and then converted into digital audio signals in the audio unit 217. Here, the gain refers to the degree of amplification of the audio data. The gain of the microphone is automatically adjusted in such a way that when the amplifying speaker 300 is connected to the headset 200, the magnitude of the signal of the audio data inputted through microphone MIC of the headset 200 is measured; and the signal magnitude is amplified or reduced to a known value.

The display 215 is implemented with a light emitting diode (LED), for example, to indicate state of the headset 200. The display 215 displays the state of the headset 200 according to the control of the controller 209.

The audio unit 217 converts an analog audio signal inputted through the microphone into a digital audio signal, and reproduces an analog audio signal converted from a digital audio signal from the controller 209, through the built-in speaker SPK.

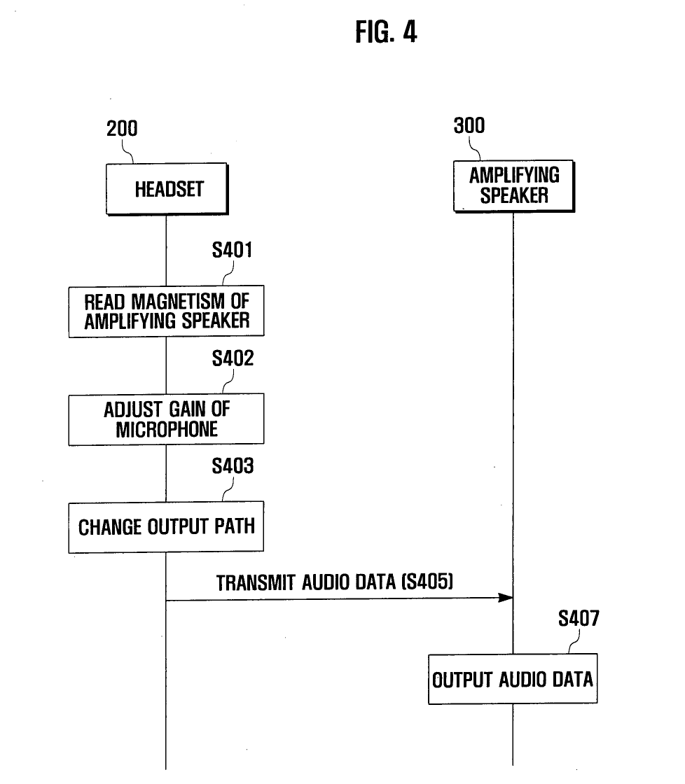

FIG. 4 is a view illustrating a procedure to output audio data transmitted through short-range wireless communication according to an embodiment of the present invention.

Referring to FIG. 4, when the headset 200 is mounted on the amplifying speaker 300, it detects or measures the magnetic field generated by the amplifying speaker 300 (S401) and adjusts the gain of the microphone MIC (S402). Specifically, when the headset 200 detects a connection to the amplifying speaker 300, it measures the magnitude of a signal of audio data inputted through the microphone MIC, and amplifies or reduces the measured signal magnitude to a known value, thereby adjusting the gain of the microphone MIC.

After that, the headset 200 changes the output path of the audio data to the amplifying speaker 300 (S403). Here, when reading or detecting the magnetic field, the switch contacting to the built-in speaker of the headset 200 contacts the output lead 203a of the headset 200, thereby changing the output path of the audio data.

Then, the headset 200 transmits the audio data to the changed output path (S405). The transmitted audio data is outputted to the amplifying speaker 300 (S407).

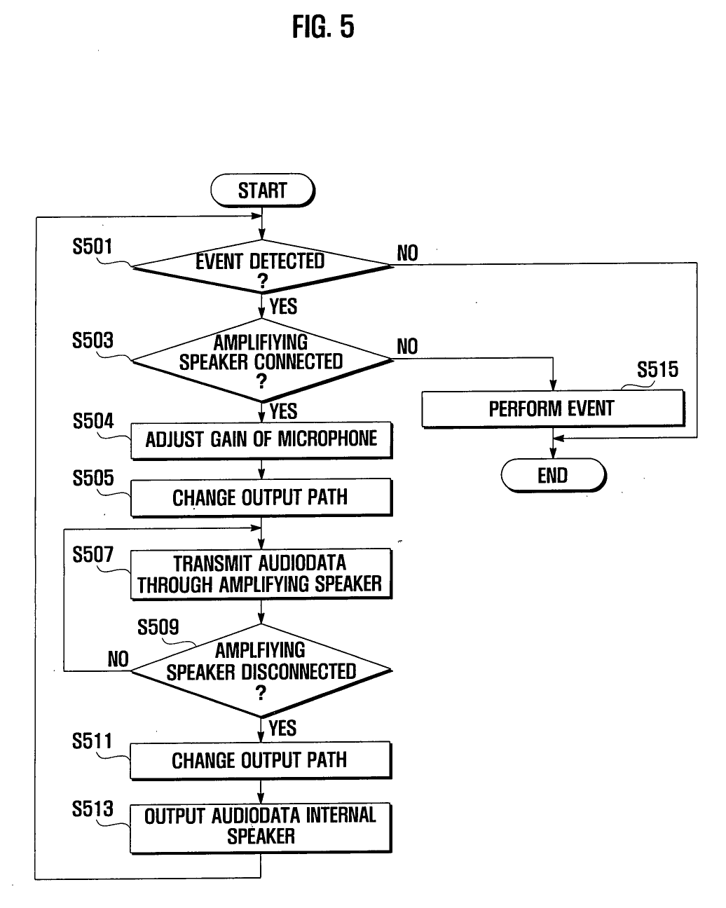

FIG. 5 is a flow chart describing a method for outputting audio data transmitted through short-range wireless communication, according to an embodiment of the present invention.

As shown in FIG. 5, the controller 209 detects whether an event has occurred, and then judges the type of the event (S501). When the controller 209 determines that the detected event corresponds to a connection to the amplifying speaker 300, it determines whether the detected event corresponds to an operation control of the headset 200 (for example, audio data output, magnetism detection, etc.) (S503). If the determination of S503 is positive, the gain of the microphone of the headset 200 is adjusted (S504). The gain of the microphone is adjusted in such a way that the gain adjusting unit 213 measures the magnitude of a signal corresponding to audio data, which is inputted through the microphone and converted to a digital audio signal and amplifies or reduces the signal magnitude to a certain critical value.

When the determination of S503 is negative, the controller 209 performs the event generated at the headset (S515), for example, audio data output, magnetism detection, etc.

The controller 209 determines whether the headset 200 is connected to the amplifying speaker 300 (S503) when the Hall sensor of the magnetism detector 211 detects the magnetism. Here, the Hall sensor is a sensor responsive to the magnetic field, and detects the magnetic field generated by the magnet built in the amplifying speaker.

When the headset 200 is connected to the amplifying speaker 300, from the determination of S503, the controller 209 changes the output path of the audio data (S505). Specifically, the output path is changed in such a way that when the magnetism of the magnet built-in the amplifying speaker 300 is detected (S503), the controller 209 directs the path controlling unit 203 to switch the switch contacting the built-in speaker of the headset 200 to the output lead 203a. The controller 209 transmits the audio data to the changed output path (S507).

After that, the controller 209 determines whether connection to the amplifying speaker 300 is disconnected (S509).

If the determination of S509 is positive, the controller 209 changes the output path of the audio data, provided to the amplifying speaker 300 through the output lead 203a, to the built-in speaker (S511).

After that, the controller 209 outputs the audio data to the built-in speaker of the headset 200.

As shown in the foregoing FIG. 5, although the present invention is described based on an embodiment where an event of connection between the headset 200 and the amplifying speaker 300 is detected, it is not limited by the illustrated embodiment. For example, the present invention is modified to be operated by an event where disconnection between the headset 200 and the amplifying speaker 300 is detected.

The above-described methods according to the present invention can be realized in hardware or as software or computer code that can be stored in a recording medium such as a CD ROM, an RAM, a floppy disk, a hard disk, or a magneto-optical disk or downloaded over a network, so that the methods described herein can be rendered in such software using a general purpose computer, or a special processor or in programmable or dedicated hardware, such as an ASIC or FPGA. As would be understood in the art, the computer, the processor or the programmable hardware include memory components, e.g., RAM, ROM, Flash, etc. that may store or receive software or computer code that when accessed and executed by the computer, processor or hardware implement the processing methods described herein.

While the present invention has been particularly shown and described with reference to embodiments thereof, it will be understood by those of ordinary skill in the art that various changes in form and detail may be made therein without departing from the spirit and scope of the present invention as defined by the following claims.

As described in the foregoing, the present invention can output audio data that is outputting to one user's headset to the amplifying speaker, thereby allowing other users to share the audio data, simultaneously.

In addition, the present invention can automatically adjust the microphone gain of the headset based on connection/disconnection events between the headset and the amplifying speaker and automatically change the output path of the audio data, thereby enhancing user's convenience.

What is claimed is:

1. A system for outputting audio data comprising:
a headset for:
outputting audio data,
adjusting gain of a microphone in response to a change control signal of an output path of the audio data, and
changing the output path of the audio data; and
an amplifying speaker for outputting the audio data transmitted through the headset.

2. The system of claim 1, wherein the headset further comprises a magnetism detector for detecting magnetism generated by the amplifying speaker.

3. The system of claim 2, wherein the headset further comprises a gain adjusting unit for adjusting the gain of the microphone when the magnetism detector detects the magnetism.

4. The system of claim 3, wherein the gain adjusting unit measures magnitude of a signal corresponding to audio data inputted through the microphone and amplifies or reduces the magnitude of the signal by a certain critical value to adjust the gain of the microphone.

5. The system of claim 2, wherein the magnetism detector comprises a Hall sensor.

6. The system of claim 2, wherein the amplifying speaker comprises a magnet.

7. The system of claim 2, wherein the headset further comprises a path controlling unit changing an output path of the audio data when detecting magnetism of the amplifying speaker.

8. The system of claim 7, wherein the path controlling unit further comprises an output lead connected to the amplifying speaker.

9. The system of claim 8, wherein the path controlling unit switches a switch that is contacting a built-in speaker of the headset through the output lead to change the output path of the audio data.

10. The system of claim 8, wherein the amplifying speaker further comprises an input lead connected to the output lead of the headset.

11. A method for outputting audio data using a headset and an amplifying speaker, comprising:
adjusting gain of a microphone of the headset when the headset reads connection to the amplifying speaker;
changing an output path of the audio data to the amplifying speaker connected to the headset; and
transmitting the audio data to the changed output path.

12. The method of claim 11, wherein the adjusting comprises:
measuring magnitude of a signal corresponding to audio data inputted through the microphone; and
amplifying/reducing the magnitude of the signal to a critical value to adjust the gain of the microphone.

13. The method of claim 11, wherein further comprising:
outputting the transmitted audio data through the amplifying speaker.

14. The method of claim 11, wherein the reading of the connection to the amplifying speaker is performed in such a way that a magnetism detector of the headset reads magnetism of a magnet of the amplifying speaker.

15. A method for outputting audio data using a headset and an amplifying speaker, comprising:
adjusting gain of a microphone of the headset when connection/disconnection of the amplifying speaker is detected, and changing an output path of the audio data;
transmitting the audio data to the changed output path; and
outputting the transmitted audio data through the amplifying speaker.

16. The method of claim 15, wherein the changing of an output path further comprises:
measuring magnitude of a signal corresponding to audio data inputted through the microphone, and amplifying/reducing the magnitude of the signal to a certain critical value to adjust the gain of the microphone; and
changing a switch contacting a built-in speaker of the headset to an output lead of the headset when detecting connection of the amplifying speaker to change the output path of the audio data.

17. The method of claim 15, further comprising:
switching a switch contacting the output lead of the headset to a built-in of the headset when detecting disconnection of the amplifying speaker to change the output path of the audio data.

18. A wireless audio distribution system comprising:
a wireless communication receiving unit comprising:
a wireless receiving unit;
an audio transmission unit;
an audio volume control; and
a magnetic detection sensor; and
an audio distribution system comprising;
an audio receiving unit including a magnetic generating a magnetic field, wherein the volume of said audio data transmitted by said transmission unit is adjusted based on the detection of the magnetic field generated by said magnetic.
